(19) United States
(12) Patent Application Publication
(10) Pub. No.: US 2008/0241972 A1
(43) Pub. Date: Oct. 2, 2008

(54) METHOD OF MANUFACTURING A SEMICONDUCTOR DEVICE, PATTERN CORRECTION APPARATUS, AND COMPUTER-READABLE RECORDING MEDIUM

(75) Inventor: Tomohiko YAMAMOTO, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kanagawa (JP)

(21) Appl. No.: 12/059,895

(22) Filed: Mar. 31, 2008

(30) Foreign Application Priority Data
Mar. 30, 2007 (JP) JP2007-094125

(51) Int. Cl. H01L 21/027; H01L 21/66

(52) U.S. Cl. 438/7; 257/E21.53; 257/E21.528; 257/E21.023

(57) ABSTRACT

A method of manufacturing a semiconductor device includes measuring a first width of a first mask pattern formed in a photomask and a second width of a second mask pattern formed in the photomask, and deciding a temperature of heat treatment of a thickening material over a resist film based on measured results.

### CROSS-REFERENCE TO RELATED APPLICATIONS

This application is based upon and claims the benefit of priority from the prior Japanese Patent Application No. 2007-94125, filed on Mar. 30, 2007, the entire content of which is incorporated herein by reference.

### BACKGROUND

The present invention relates to a method of manufacturing a semiconductor device using a lithographic process.

Various techniques have been progressed for the purposes of forming finer patterns by lithography and obtaining finer photomasks to form the finer patterns. Corresponding to this tendency, it is necessary to realize higher accuracy in mask dimension. In relation thereto, a technique of performing Optical Proximity Correction (OPC) on a photomask is well known.

However, manufacturing errors are necessarily caused when the photomask is manufactured. If a mask pattern of the photomask including the manufacturing errors is transferred onto a substrate, a resist pattern is formed which has a dimension differing from the initially estimated dimension. More specifically, when a transfer process is performed by using different photomasks which have been subjected to the same OPC, the resist patterns differ from each other corresponding to the dimensional errors of the photomasks. For example, when two photomasks are used to form patterns in the same layer of the same product in a mass-production factory, etc., these two photomasks provide different transfer results. Consequently, variations are generated in the product function, production yield, and process control, whereby a serious problem is caused in device manufacturing.

### SUMMARY

According to one aspect of the present invention, a method of manufacturing a semiconductor device includes measuring a first width of a first mask pattern formed in a photomask and a second width of a second mask pattern formed in the photomask, and deciding a temperature of heat treatment of a thickening material over a resist film based on measured results.

### BRIEF DESCRIPTION OF THE DRAWINGS

FIG. 1 is a block diagram of a resist pattern correction apparatus according to a first embodiment of the present invention;

FIGS. 2A and 2B are schematic sectional views showing a resist pattern forming method according to the first embodiment;

FIG. 3 is a flowchart showing the resist pattern forming method according to the first embodiment;

FIG. 4 is a characteristic graph showing the relationship, used in the first embodiment, of heat treatment temperature in a thickening step with respect to a differential value between the amount of dimension change of a coarse resist pattern and the amount of dimension change of a dense resist pattern;

FIG. 5 is a schematic view of a photomask used in the first embodiment;

FIG. 6 is a block diagram of a resist pattern correction apparatus according to a modification of the first embodiment;

FIG. 7 is a flowchart showing a resist pattern forming method according to the modification of the first embodiment;

FIGS. 8A and 8B are schematic sectional views of a MOS transistor manufacturing method according to a second embodiment of the present invention; and

FIG. 9 is a schematic view showing an internal configuration of a personal user terminal.

### DESCRIPTION OF THE PREFERRED EMBODIMENTS

The technique of thickening the resist pattern was initially developed as a technique for downsizing contact holes and multilayered wiring. For example, a contact hole with a diameter of 65 nm is formed through the steps of forming a resist pattern, which has an opening with a diameter of, e.g., 70 nm corresponding to the objective contact hole, by using a first resist material, coating a second resist material on the formed resist pattern, performing heat treatment, and washing the resist pattern. With that technique, the resist pattern is thickened about 5 nm, for example, so that the objective contact hole with the diameter of about 65 nm is obtained.

A preferable combination of the first resist material and the second resist material is given, for example, by employing a chemical amplification resist, which contains polyhydroxystyrene or an acrylic resin, as the first resist material and polyvinyl alcohol as the second resist material. Other examples of the resist materials usable in the present invention are described in, e.g., Japanese Laid-open Patent Publication No. 2006-18095.

With the technique of thickening the resist pattern, an acid residual component after the exposure and the second resist material are bridged with each other through the subsequent heat treatment, whereby the resist pattern is thickened, because the amount of the acid residual component differs depending on the resist pattern.

According to the present invention, the degree of thickening of the resist pattern is determined depending on the heat treatment temperature of the coated second resist material, and the heat treatment temperature is a parameter contributing to a mechanism which determines the amount of dimension change caused by the thickening. Based on the above finding as to the relationship between the amount of the dimension change of the resist pattern and the heat treatment temperature in a thickening step, the dimensional error of a photomask is eliminated by optimizing the lithographic process by utilizing the above-described characteristic of the thickening technique.

More specifically, the relationship between the dimension of the resist pattern, which is changed by the thickening, and the heat treatment temperature in the thickening step is obtained in advance.

The dimension of a mask pattern is measured and the measured result is applied to the above-mentioned relationship, to thereby decide the heat treatment temperature that is optimum to thicken the resist pattern to the desired dimension.

By employing the above-described method, the dimensional error of the mask pattern in the photomask is suppressed.

Embodiments of the present invention will be described in detail below with reference to the drawings. It is to be noted that components or members common to the embodiments are denoted by the same reference symbols.

A first embodiment is described in connection with a resist pattern correction apparatus and a resist pattern forming method using the correction apparatus. The following description is given of the case forming two resist patterns having different pitches i.e., a coarse resist pattern and a dense resist pattern.

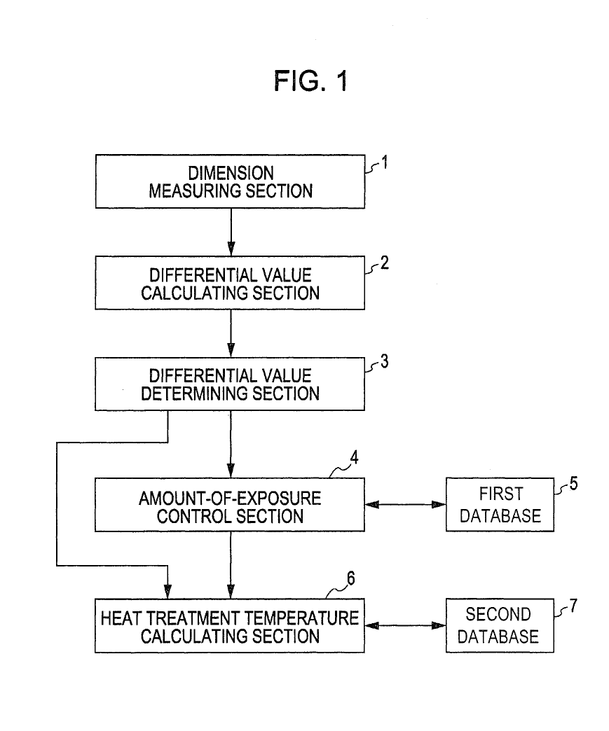

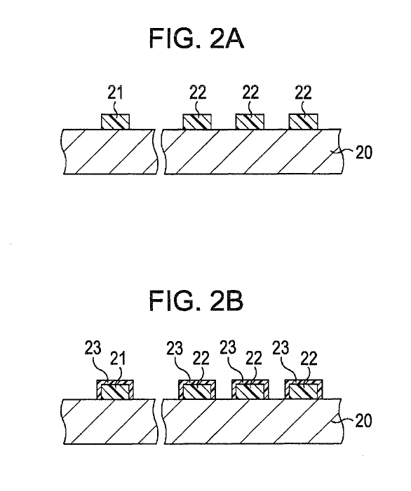

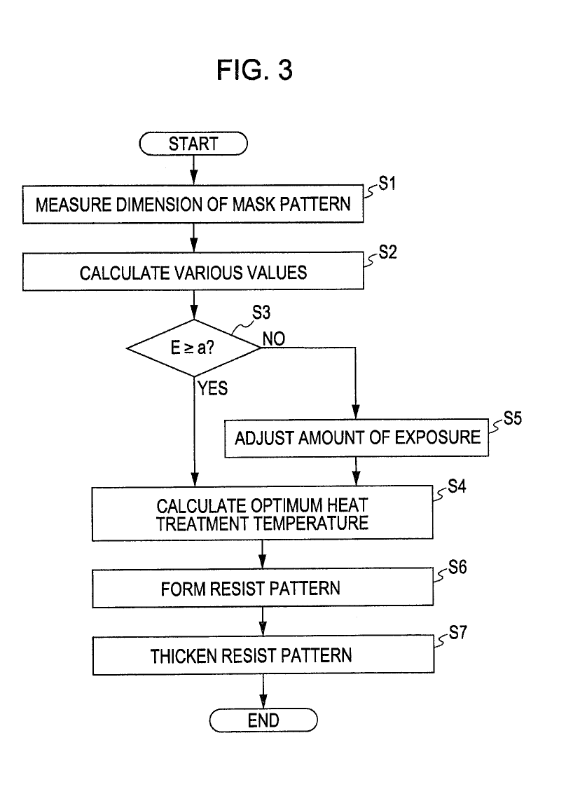

FIG. 1 is a block diagram of the resist pattern correction apparatus, FIGS. 2A and 2B are schematic sectional views showing the resist pattern forming method, and FIG. 3 is a flowchart showing the resist pattern forming method.

The resist pattern correction apparatus comprises a dimension measuring section 1, a differential value calculating section 2, a differential value determining section 3, an amount-of-exposure control section 4, a first database 5, a heat treatment temperature calculating section 6, and a second database 7.

The dimension measuring section 1 measures the dimension of the mask pattern formed in the photomask and includes, for example, a Scanning Electron Microscope (SEM), etc. Stated another way, the dimension measuring section 1 performs dimension measurement for each of the mask patterns which are formed at different densities in the photomask set in place. Herein, it is assumed that there are two mask patterns, i.e., a coarse mask pattern and a dense mask pattern. Measured values of the mask pattern dimensions are sent to the differential value calculating section 2.

The differential value calculating section 2 calculates a variation amount C1 of dimension value of the coarse resist pattern, which corresponds to the measured dimension value of the coarse mask pattern, from a target value A1 of the dimension of the coarse mask pattern, a variation amount C2 of dimension value of the dense resist pattern, which corresponds to the measured dimension value of the dense mask pattern, from a target value A2 of the dimension of the dense mask pattern, a differential value D between C1 and C2, and an absolute value E of D as a magnitude of the differential value. Herein, assuming that the dimension values of the coarse resist pattern and the dense resist pattern which are obtained from the measured dimension values of the coarse mask pattern 11 and the dense mask pattern 12 are B1 and B2, C1 and C2 are given respectively by C1=B1−A1 and C2=B2−A2.

Regarding each of A1 and A2, the measured dimension value of the mask pattern uniquely corresponds to the dimension of the resist pattern transferred to a resist through the exposure by using the mask pattern. In other words, if the dimension value of the mask pattern is measured, the dimension of the resist pattern can be obtained from the measured dimension value.

The differential value determining section 3 determines whether the absolute value E calculated in the differential value calculating section 2 is not less than a predetermined value. If the absolute value E is not less than the predetermined value, e.g., 0.5 nm, the differential value D is sent to the heat treatment temperature calculating section 6. On the other hand, if the absolute value E is less than 0.5 nm, the variation amounts C1 and C2 are sent to the amount-of-exposure control section 4.

The first database 5 stores, for each resist pattern, the relationship between the amount of dimension change of the resist pattern and the amount of change of exposure.

The amount-of-exposure control section 4 accesses the first database 5 and obtains the optimum amount of change of exposure from one of the values sent from the differential value determining section 3, e.g., the variation amount C2 of dimension value of the dense resist pattern. Further, the amount-of-exposure control section 4 controls the amount of exposure i.e., exposure energy set in an exposure apparatus.

With the control of the amount of exposure, the other value input from the differential value determining section 3, i.e., the variation amount C1 of dimension value of the coarse resist pattern, is also changed. Because an exposure margin differs for each of the resist patterns, a dimension adjustment cannot be performed uniformly for both the coarse resist pattern and the dense resist pattern. Herein, the variation amount C2 of dimension value of the dense resist pattern is adjusted to C2=0 with the control of the amount of exposure, and therefore a variation amount C1′ changed with the adjustment of C2 represents the differential value D.

The amount-of-exposure control section 4 sends the variation amount C1′ changed with the adjustment of C2, as the differential value D, to the heat treatment temperature calculating section 6. The amount-of-exposure control section 4 is provided as a part of the exposure apparatus.

The second database 7 stores the relationship between the differential value between the dimensions of the two resist patterns, which are changed by the thickening, and the heat treatment temperature in the thickening step, the relationship being obtained in advance.

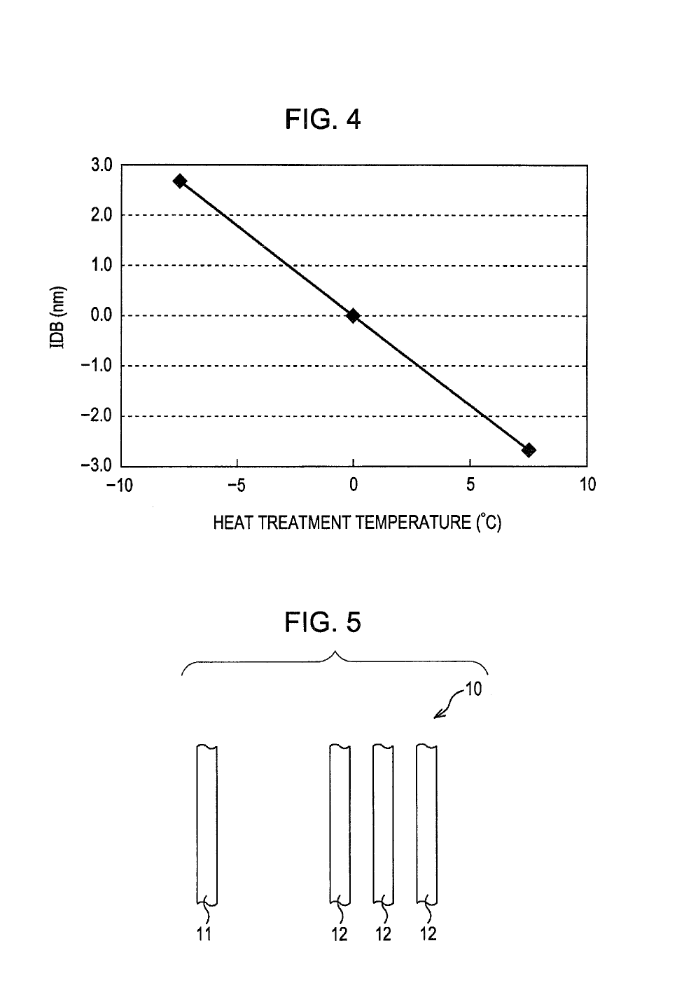

More specifically, the relationship between the differential value between the dimensions of the two resist patterns, which are changed by the thickening, i.e., the difference in dimension change depending on the pattern density and the heat treatment temperature in the thickening step of the resist pattern is obtained, for example, as shown in FIG. 4 by experiments. In FIG. 4, the vertical axis represents the dimensional differential value (nm) between the amount of dimension change of the coarse resist pattern and the amount of dimension change of the dense resist pattern, and the horizontal axis represents the heat treatment temperature (° C.) in the thickening step. On an assumption that the preset heat treatment temperature e.g., 80° C. in the thickening step is the center of the heat treatment temperature, FIG. 4 shows the experimentally obtained result of the relationship between temperature change from the center of the heat treatment temperature and the above-described dimensional differential value. In the illustrated example, the dimensional differential value of 2.6 nm results in a change of 7.5° C. from the preset center of the heat treatment temperature. Thus, the relationship shown in FIG. 4 is stored in the second database 7.

The heat treatment temperature calculating section 6 accesses the second database 7 and decides, based on the differential value D input from the differential value determining section 3 or the amount-of-exposure control section 4, the optimum heat treatment temperature for thickening the resist pattern to the desired dimension. The optimum heat treatment temperature is the temperature for eliminating the dimensional differential value between the coarse resist pattern and the dense resist pattern.

The resist pattern forming method using the thus-constructed resist pattern correction apparatus will be described below with reference to FIGS. 2A, 2B and 3. The following description is given, by way of example, in connection with the case where the resist patterns are formed by using the coarse mask pattern 11 and the dense mask pattern 12 shown in FIG. 5. The coarse mask pattern 11 corresponds to the coarse resist pattern, and the dense mask pattern 12 corresponds to the dense resist pattern.

Each of Table 1 and Table 2 lists target dimension values A1 and A2 of the coarse resist pattern and the dense resist pattern, actual dimension values B1 and B2 thereof, the variation amounts C1 and C2 of dimension values of the coarse resist pattern and the dense resist pattern from A1 and A2, the differential value D between the variation amount C1 of dimension value of the coarse resist pattern from the target value A1 and the variation amount C2 of dimension value of the dense resist pattern from the target value A2, and the absolute value E of the differential value D.

TABLE 1

| | Coarse Resist Pattern | Dense Resist Pattern |
|---|---|---|
| | (1) | (2) |
| Target Value A | 70 nm | 60 nm |
| Actual value B | 69 nm | 61 nm |
| Variation Amount C | −1 nm | 1 nm |

| | |
|---|---|
| Differential Value D | −2 nm |
| Absolute Value E | 2 nm |

TABLE 2

| | Coarse Resist Pattern | Dense Resist Pattern |
|---|---|---|
| | (1) | (2) |
| Target Value A | 70 nm | 60 nm |
| Actual value B | 72 nm | 62 nm |
| Variation Amount C | +0.5 nm | 0 nm |

| | |
|---|---|
| Differential Value D | +0.5 nm |
| Absolute Value E | 0.5 nm |

First, the dimension measuring section 1 measures the dimension values of the coarse mask pattern 11 and the dense mask pattern 12 which are formed in the photomask 10 in the step S1. The measured values are sent from the dimension measuring section 1 to the differential value calculating section 2.

Then, the differential value calculating section 2 calculates various values, i.e., the variation amounts C1 and C2 of dimension values of the coarse resist pattern and the dense resist pattern from the target values A1 and A2, the differential value D between C1 and C2, and the absolute value E of the differential value D in the step S2.

Then, the differential value determining section 3 determines whether the absolute value E calculated in the differential value calculating section 2 is not less than a predetermined value a, e.g., 0.5 nm herein in the step S3.

If the absolute value E is not less than the predetermined value a, this can be regarded as indicating that the heat treatment temperature calculating section 6 can decide a proper heat treatment temperature based on the differential value D corresponding to the absolute value E. On the other hand, if the absolute value E is less than the predetermined value a, this indicates that the proper heat treatment temperature cannot be decided based on the differential value D corresponding to the absolute value E. Accordingly, as described below, after adjusting the dimension of one resist pattern e.g., the dense resist pattern herein by controlling the amount of exposure, the differential value D is calculated again.

Thus, if the absolute value E calculated in step S3 is not less than 0.5 nm, the differential value D is sent to the heat treatment temperature calculating section 6. On the other hand, if the calculated absolute value E is less than 0.5 nm, the variation amounts C1 and C2 are sent to the amount-of-exposure control section 4.

For example, Table 1 represents the former case because the absolute value E is 2.0 nm, while Table 2 represents the latter case because the absolute value E is 0 nm.

If the determination in step S3 indicates the former case where the calculated absolute value E is not less than 0.5 nm, the heat treatment temperature calculating section 6 accesses the second database 7 and decides, based on the differential value D input from the differential value determining section 3, the optimum heat treatment temperature for eliminating the dimensional differential value between the coarse resist pattern and the dense resist pattern in the step S4.

In the case of Table 1, for example, because the differential value D is −2.0 nm, it is understood in consideration of the relationship of FIG. 4 that the optimum heat treatment temperature is given by adding 5.6° C. to 800C that is the preset heat treatment temperature in the thickening step, i.e., 80° C.+5.6° C.=85.6° C.

On the other hand, if the determination in step S3 indicates the latter case where the calculated absolute value E is less than 0.5 nm, the amount-of-exposure control section 4 accesses the first database 5 and decides the optimum amount of exposure or the optimum change amount of exposure based on the variation amount C2 of dimension of the dense resist pattern, which has been input from the differential value determining section 3, thereby controlling the amount of exposure set in the exposure apparatus in the step S5.

In step S5, the other value input from the differential value determining section 3, i.e., the variation amount C1 of the dimension of the coarse resist pattern, is changed to C1′ with the control of the amount of exposure. Since the one value input from the differential value determining section 3, i.e., the variation amount C2 of the dimension of the dense resist pattern, is adjusted to 0 with the control of the amount of exposure, the changed variation amount C1′ can be regarded as the differential value D. Accordingly, the amount-of-exposure control section 4 sends, as the differential value D, the changed variation amount C1′ to the heat treatment temperature calculating section 6.

In the case of Table 2, for example, the differential value D is given by 0.5 nm i.e., the actual value B1 (70.5 nm)−the target value A1 (70 nm)=0.5 nm.

In the step S4 subsequent to the step S5, the heat treatment temperature calculating section 6 accesses the second database 7 and decides, based on the differential value D input from the amount-of-exposure control section 4, the optimum heat treatment temperature for thickening the resist patterns to the desired dimensions.

In the case of Table 2, for example, because the differential value D is +0.5 nm, it is understood in consideration of the relationship of FIG. 4 that the optimum heat treatment temperature is given by subtracting 1.4° C. from 80° C. that is the preset heat treatment temperature in the thickening step, i.e., 80° C.−1.4° C.=78.6° C.

Then, as shown in FIG. 2A, a coarse resist pattern 21 and a dense resist pattern 22 are formed in the step S6.

More specifically, a resist is coated over a semiconductor substrate 20 or a predetermined layer formed over the semiconductor substrate 20, and the coarse mask pattern 11 and the dense mask pattern 12 are transferred to the resist with exposure by using the photomask 10. Herein, the resist is formed using, e.g., a chemical amplification resist, which contains polyhydroxystyrene or an acrylic resin. Through subsequent steps including development, etc., the coarse resist pattern 21 and the dense resist pattern 22 are formed over the semiconductor substrate 20 corresponding to the coarse mask pattern 11 and the dense mask pattern 12, respectively.

Then, as shown in FIG. 2B, the coarse resist pattern 21 and the dense resist pattern 22 are thickened by the thickening technique of step S7.

More specifically, a thickening material 23 is coated so as to cover the coarse resist pattern 21 and the dense resist pattern 22. Polyvinyl alcohol, for example, is used herein as the thickening material 23. The semiconductor substrate 20 is then subjected to the heat treatment at the temperature decided through the above-described steps S1-S5. Thereafter, the semiconductor substrate 20 is washed by, e.g., pure water or pure water containing a surfactant, to thereby remove the waste thickening material. As a result, the coarse resist pattern 21 and the dense resist pattern 22 are thickened by the thickening material 23. Since the coarse resist pattern 21 and the dense resist pattern 22 are thickened at the heat treatment temperature decided as described above, it is possible to form the desired coarse resist pattern 21 and dense resist pattern 22 in which dimensional deviations of the transferred patterns caused by respective dimensional deviations of the coarse mask pattern 11 and the dense mask pattern 12 in the photomask 10 are eliminated.

A modification of the first embodiment will now be described. As in the first embodiment, the modification is described in connection with a resist pattern correction apparatus and a resist pattern forming method using the correction apparatus. However, the resist pattern correction apparatus and the flow of the resist pattern forming method according to the modification differ in several points from those according to the first embodiment.

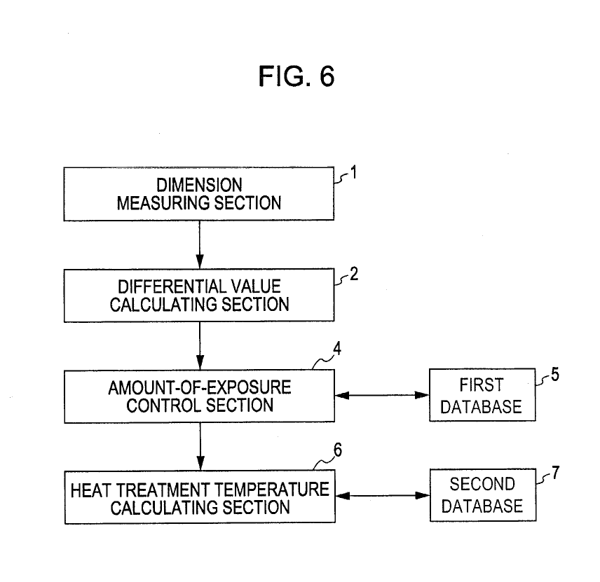

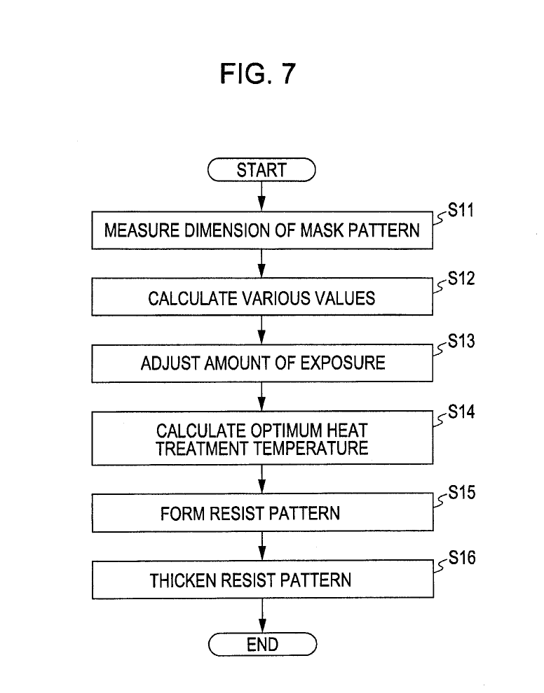

FIG. 6 is a block diagram of the resist pattern correction apparatus according to the modification of the first embodiment, and FIG. 7 is a flowchart showing a resist pattern forming method according to the modification of the first embodiment in the order of steps.

While the resist pattern correction apparatus according to the modification is basically similar to that according to the first embodiment shown in FIG. 1, it does not include the differential value determining section 3. In other words, the resist pattern correction apparatus according to the modification comprises a dimension measuring section 1, a differential value calculating section 2, an amount-of-exposure control section 4, a first database 5, a heat treatment temperature calculating section 6, and a second database 7.

The resist pattern forming method using the thus-constructed resist pattern correction apparatus will be described below with reference to FIGS. 4 and 5 which have been referred to in the above description of the first embodiment.

Table 3 lists the target dimension values A1 and A2 of the coarse resist pattern and the dense resist pattern, the actual dimension values B1 and B2 thereof i.e., the dimension values of the coarse resist pattern and the dense resist pattern which are obtained respectively from the measured values of the coarse mask pattern 11 and the dense mask pattern 12, the variation amounts C1 and C2 of dimension values of the coarse resist pattern and the dense resist pattern from A1 and A2, and the differential value D between the variation amount C1 of dimension value of the coarse resist pattern from the target value A1 and the variation amount C2 of dimension value of the dense resist pattern from the target value A2.

TABLE 3

| | Coarse Resist Pattern | Dense Resist Pattern |
|---|---|---|
| | (1) | (2) |
| Target Value A | 70 nm | 60 nm |
| Actual value B | 69 nm | 61 nm |
| Variation Amount C | −2 nm | 0 nm |

| | |
|---|---|
| Differential Value D | −2 nm |

First, the dimension measuring section 1 measures the dimension values of the coarse mask pattern 11 and the dense mask pattern 12 which are formed in the photomask 10 in the step S11. The measured values are sent from the dimension measuring section 1 to the differential value calculating section 2.

Then, the differential value calculating section 2 calculates the variation amounts C1 and C2 of dimension values of the coarse resist pattern and the dense resist pattern from the target values A1 and A2 step S12. The calculated variation amounts C1 and C2 are sent from the differential value calculating section 2 to the amount-of-exposure control section 4.

Then, the amount-of-exposure control section 4 accesses the first database 5 and decides the optimum change amount of exposure or the optimum change amount of exposure based on one of the variation amounts C1 and C2 input from the differential value determining section 3 e.g., the variation amount C2 of dimension of the coarse resist pattern herein, thereby controlling the amount of exposure set in the exposure apparatus in the step S13.

Then, the amount-of-exposure control section 4 sends, as the differential value D, a value C1′ to which the variation amount C1 of the dimension of the coarse resist pattern, i.e., the other value input from the differential value calculating section 2, has been changed with the control of the amount of exposure, to the heat treatment temperature calculating section 6.

In the case of Table 3, for example, the differential value D is given by −2.0 nm.

Then, the heat treatment temperature calculating section 6 accesses the second database 7 and decides, based on the differential value D input from the amount-of-exposure control section 4, the optimum heat treatment temperature for eliminating the dimensional differential value between the coarse resist pattern and the dense resist pattern in the step S14.

In the case of Table 3, for example, because the differential value D is −2.0 nm, it is understood in consideration of the relationship of FIG. 4 that the optimum heat treatment temperature is given by adding 5.6° C. to 80° C. that is the preset heat treatment temperature in the thickening step, i.e., 80° C.+5.6° C.=85.6° C.

Thereafter, steps S15 and S16 are performed in the same manner as steps S6 and S7 in the first embodiment. As a result, the desired coarse resist pattern 21 and dense resist pattern 22 are formed such that dimensional deviations of the transferred patterns caused by respective dimensional deviations of the coarse mask pattern 11 and the dense mask pattern 12 in the photomask 10 are eliminated.

A second embodiment of the present invention is described in connection with the case where a semiconductor device, e.g., a MOS transistor, is manufactured by using the resist pattern forming method described in the first embodiment.

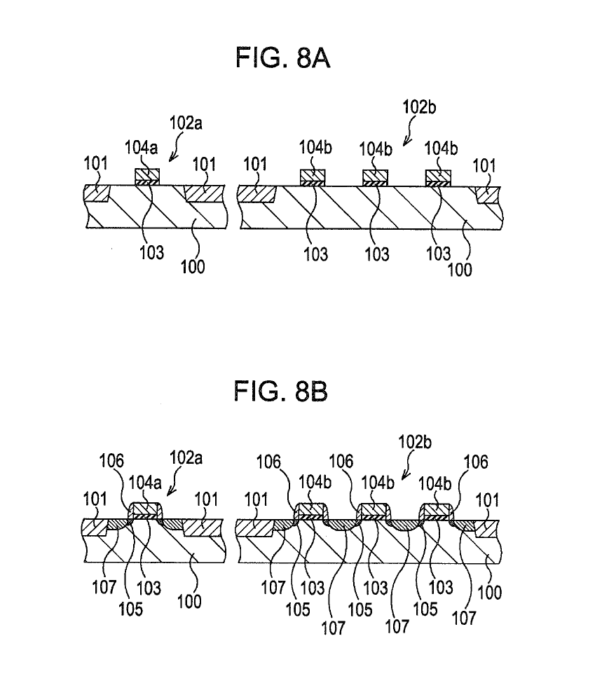

FIGS. 8A and 8B are schematic sectional views for explaining a MOS transistor manufacturing method according to the second embodiment in the order of steps.

As shown in FIG. 8A, gate layers 104a and 104b are formed.

More specifically, on a semiconductor substrate 100 of silicon, device isolation structures 101 are formed by using the Shallow Trench Isolation (STI) process, for example, to define active regions 102a and 102b. The active region 102a represents an area in which gate electrodes are formed coarsely e.g., in an isolated state, and the active region 102b represents an area in which gate electrodes are formed densely e.g., in a line and space pattern of 1:1.

Then, the surfaces of the active regions 102a and 102b are subjected to thermal oxidation, for example, to form thin insulating films 103. Over the gate insulating films 103, conductive films, e.g., polycrystalline silicon films are deposited by the CVD process, for example.

Then, by performing steps S1-S7 of the resist pattern forming method described above, the coarse resist pattern 21 and the dense resist pattern 22 are formed in the active region 102a and the active region 102b, respectively. Further, the polycrystalline silicon films and the gate insulating films 103 are processed by dry etching while the resist patterns 21 and 22 are used as masks, thereby forming a gate layer 104a in the active region 102a in match with the coarse resist pattern 21 and gate layers 104b in the active region 102b in match with the dense resist pattern 22, respectively.

Then, as shown in FIG. 8B, sources/drains regions 107 are formed.

More specifically, after removing the resist patterns 21 and 22 by, e.g., ashing, Lightly Doped Drain (LDD) 105 are formed by ion-injecting an impurity e.g., boron in the case of a PMOS transistor and phosphorus or arsenic in the case of an NMOS transistor at a relatively low concentration in surface layers of the active regions 102a and 102b while the gate electrodes 104a and 104b are used as masks.

Then, an insulating film, e.g., a silicon oxide film, is deposited over an entire surface so as to cover the gate electrodes 104a and 104b by the CVD process, for example. The silicon oxide film is entirely subjected to anisotropic etching. As a result of the etch back, the silicon oxide film remains only at both side surfaces of each of the gate electrodes 104a and 104b, whereby side wall spacers 106 are formed.

Then, an impurity, e.g., boron in the case of the PMOS transistor and phosphorus or arsenic in the case of the NMOS transistor, is ion-injected at a higher concentration than the LDD regions 105 in the surface layers of the active regions 102a and 102b while the gate electrodes 104a and 104b and the side wall spacers 106 are used as masks. As a result, the sources/drains regions 107 are formed in an overlapped relation to the LDD regions 105.

Thereafter, the MOS transistor is completed through the steps of forming interlayer insulating films, wiring layers electrically connected to the sources/drains regions 107, and so on.

While the above description is made, by way of example, in connection with the case where the LDD regions 105 and the sources/drains regions 107 are formed as the same regions for both the active regions 102a and 102b, they can be formed as N-type regions for one of the active regions 102a and 102b and P-type regions for the other active region, or they can be formed at different impurity concentrations between the active regions 102a and 102b.

The functions of the differential value calculating section 2, the differential value determining section 3, the amount-of-exposure control section 4, the heat treatment temperature calculating section 6 in the first embodiment shown in FIG. 1, program codes for executing steps S1-S7 in the first embodiment shown in FIG. 3 and steps S11-S16 in the modification shown in FIG. 7, etc. can be implemented with operations of programs stored in a RAM or a ROM that is incorporated in a computer. Therefore, those programs and a computer-readable recording medium recording those programs are also included in embodiments of the present invention.

More specifically, the above-mentioned programs are provided to the computer by being recorded on a recording medium, e.g., a CD-ROM, or by being transmitted through any of various transmission media. Examples of the recording medium recording the programs include, in addition to a CD-ROM, a flexible disk, a hard disk, a magnetic tape, a magneto-optical disk, and a nonvolatile memory card. Examples of the program transmission media include communication media, such as wired lines, optical fibers, and wireless lines, in computer networks, such as a LAN, a WAN, the Internet, and a wireless communication network, which can provide program information by transmitting the information in the form of carrier waves.

The functions of the above-described embodiments can also be implemented in not only the case where the computer executes the provided programs, but also the case where the programs cooperate with an Operating System (OS) running on the computer or other application software, etc., thereby implementing the functions of the above-described embodiments, and the case where a function extension board or a function extension unit for the computer executes the whole or a part of processing of the supplied programs, thereby implementing the functions of the above-described embodiments. The programs used in those cases can also be included in embodiments of the present invention.

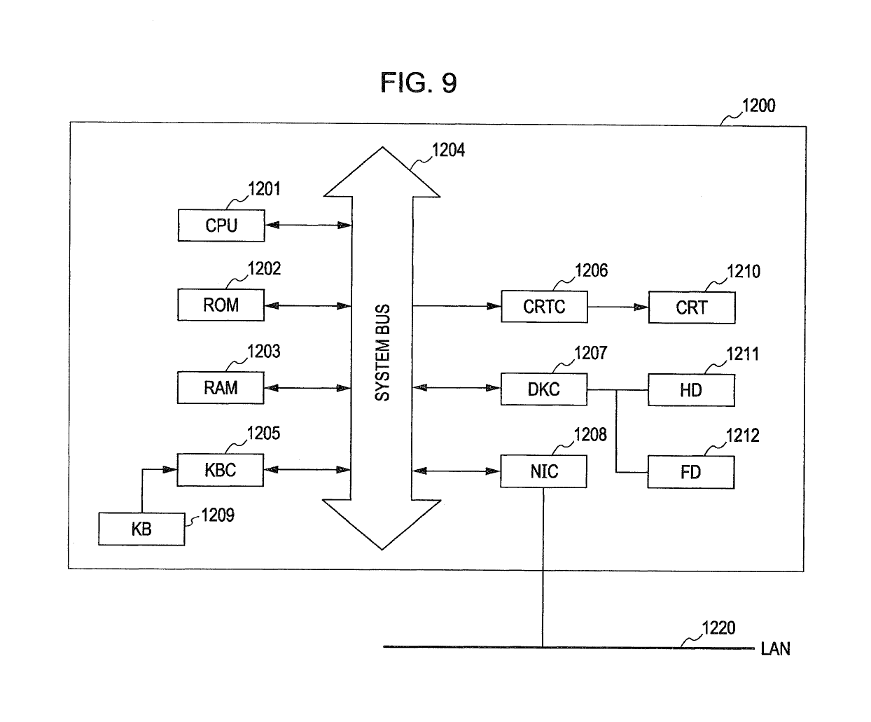

FIG. 9 is a schematic view showing, by way of example, an internal configuration of a personal user terminal.

In FIG. 9, reference numeral 1200 denotes a personal computer PC. The PC 1200 includes a CPU 1201 and executes device control software that is stored in a ROM 1202 or a hard disk (HD) 1211 or that is supplied from a flexible disk drive (FD) 1212, thereby controlling various devices connected to a system bus 1204 in a supervising manner.

The functions of the components shown in FIG. 1, the steps shown in FIGS. 3 and 7, etc. in the above-described embodiments are implemented by utilizing the CPU 1201 of the PC 1200 and programs stored in the ROM 1202 or the HD 1211.

Reference numeral 1203 denotes a RAM that serves as a main memory, a work area, etc. for the CPU 1201. A keyboard controller (KBC) 1205 controls command inputs from a keyboard (KB) 1209, a not-shown device, etc.

Reference numeral 1206 denotes a CRT controller (CRTC) that controls views displayed on a CRT display (CRT) 1210. A disk controller (DKC) 1207 controls accesses to the FD 1212 and the HD 1211 storing a program for starting execution of hardware and software of the computer, applications, edit files, user files, a network management program, etc.

Reference numeral 1208 denotes a network interface card (NIC) that transfers data in two ways with respect to a network printer, other network equipment, or other PCs via a LAN 1220.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A method of manufacturing a semiconductor device comprising:
measuring a first width of a first mask pattern formed in a photomask and a second width of a second mask pattern formed in the photomask;
forming a resist over a member to be etched;
transferring the first mask pattern and the second mask pattern to the resist, and forming a first resist pattern and a second resist pattern;
coating a thickening material to cover the first resist pattern and the second resist pattern;
deciding a temperature of heat treatment based on measured results;
executing the heat treatment of the thickening material at the temperature; and
etching the member using the first resist pattern and the second resist pattern.

2. The method of claim 1, further comprising:
determining a relationship between the temperature of the heat treatment and dimension changes of the first resist pattern and the second resist pattern in the heat treatment for the thickening.

3. The method of claim 1, wherein a relationship of x<y is satisfied in which x is a distance between the first mask pattern and a third mask pattern adjacent to the first mask pattern and y is a distance between the second mask pattern and a fourth mask pattern adjacent to the second mask pattern.

4. The method of claim 1, further comprising:
deciding an amount of exposure based on a relationship between the amount of exposure and amounts of dimension changes of the first resist pattern and the second resist pattern.

5. The method claim 1, wherein the resist contains polyhydroxystyrene or an acrylic resin.

6. The method of claim 1, wherein the thickening material is polyvinyl alcohol.

7. The method of claim 1, wherein the first mask pattern corresponds to a gate electrode of a transistor formed over a semiconductor substrate.

8. The method of claim 1, wherein, in deciding the temperature of the heat treatment for the thickening, the temperature is decided based on a first difference between a design value of the first mask pattern and the first width of the first mask pattern and a second difference between a design value of the second mask pattern and the second width of the second mask pattern.

9. The method of claim 8, wherein, in deciding the temperature of the heat treatment for the thickening, the temperature is decided based on a third difference between the first difference and the second difference.

10. A pattern correction apparatus comprising:
a measurement section measuring a first width of a first mask pattern formed in a photomask and a second width of a second mask pattern formed in the photomask; and
a heat treatment temperature calculating section deciding, based on results measured by the measurement section, a temperature of heat treatment for a thickening material that is coated over a first resist pattern corresponding to the first mask pattern and a second resist pattern corresponding to the second mask pattern.

11. The pattern correction apparatus according to claim 10, wherein the measurement section calculates a first difference between the first width of the first mask pattern and a design width of the first mask pattern and a second difference between the second width of the second mask pattern and a design width of the second mask pattern.

12. The pattern correction apparatus according to claim 10, wherein the heat treatment temperature calculating section decides, based on the first difference and the second difference, the temperature of the heat treatment by using a relationship of the temperature of the heat treatment with respect to a first change amount of width of the first resist pattern and a second change amount of width of the second resist pattern.

13. The pattern correction apparatus according to claim 10, wherein a relationship of x<y is satisfied in which x is a distance between the first mask pattern and a third pattern adjacent to the first mask pattern and y is a distance between the second mask pattern and a fourth pattern adjacent to the second mask pattern.

14. A computer-readable recording medium storing a program causing a computer to execute operations comprising:
causing a measurement section to measure a first width of a first mask pattern formed in a photomask and a second width of a second mask pattern formed in the photomask; and
causing a heat treatment temperature calculating section to decide, based on results measured by the measurement section, a temperature of heat treatment for a thickening material that is coated over a first resist pattern corresponding to the first mask pattern and a second resist pattern corresponding to the second mask pattern.

15. The computer-readable recording medium according to claim 14, further comprising causing the measurement section to calculate a first difference between the first width of the first mask pattern and a design width of the first mask pattern and a second difference between the second width of the second mask pattern and a design width of the second mask pattern.

16. The computer-readable recording medium according to claim 14, wherein the program causes the heat treatment temperature calculating section to decide, based on the first difference and the second difference, the temperature of the heat treatment by using a relationship of the temperature of the heat treatment with respect to a first change amount of width of the first resist pattern and a second change amount of width of the second resist pattern, which are caused by the heat treatment.
